(19) United States
(12) Patent Application Publication
(10) Pub. No.: US 2024/0210883 A1
(43) Pub. Date: Jun. 27, 2024

(54) WATCH DIAL COMPRISING A LIGHTING DEVICE

(71) Applicant: ETA SA Manufacture Horlogère Suisse, Grenchen (CH)

(72) Inventors: Sylvain HUOT-MARCHAND, Eschert (CH); Dominique DUBUGNON, Saint-Prex (CH)

(73) Assignee: ETA SA Manufacture Horlogère Suisse, Grenchen (CH)

(21) Appl. No.: 18/502,163

(22) Filed: Nov. 6, 2023

(30) Foreign Application Priority Data
Dec. 22, 2022 (EP) 22215943.6

(51) Int. Cl. G04B 19/32; G04C 10/02

(52) U.S. Cl. CPC G04B 19/32; G04C 10/02

(57) ABSTRACT

A dial for a watch including an autonomous lighting device including the following functional elements: at least one luminous source, an autonomous power supply unit, and a control unit for managing the operation of the at least one luminous source, the dial being formed by an assembly of a plurality of stacked layers connected together and each including one or more functional elements of the autonomous lighting device.

### TECHNICAL FIELD OF THE INVENTION

The present invention relates to a watch dial with a completely autonomous lighting device.

### TECHNOLOGICAL BACKGROUND

In the prior art, various types of lighting devices have been proposed for watches to enable the time to be read in low-light conditions. These devices are essentially based on the presence of phosphorescent materials on the dials of these watches. Such materials have been used with varying degrees of success, as they all suffer from the well-known disadvantage of diminishing effectiveness over time. In addition, these materials generally require periodic recharging by exposure to light to maintain the level of phosphorescent emissions.

In this context, it is understood that there is a need to find a solution that does not have the disadvantages of the prior art.

### SUMMARY OF THE INVENTION

The purpose of the invention is to overcome these disadvantages by offering a watch whose dial illumination has an efficiency that remains constant over time.

One aspect of the invention relates to a dial for a watch comprising an autonomous lighting device including the following functional elements:
at least one luminous source,
an autonomous power supply unit, and
a control unit for managing the operation of said at least one luminous source, said dial being formed by an assembly of a plurality of stacked layers connected together and each including one or more functional elements of the autonomous lighting device.

Another aspect of the invention relates to:
the assembly consists of a first layer forming a visible face of the dial comprising at least one luminous source;
said first layer is configured to be traversed in whole or in part by light radiation, in particular solar radiation
said first layer is wholly or partly transparent or translucent;
the assembly includes a second layer comprising a photovoltaic module constituting the autonomous power supply unit;
the second layer comprises a substrate on which the photovoltaic module is printed;
said photovoltaic module is disposed on an active area of said second layer, said area being configured to receive light rays from the first layer of the assembly;
the assembly includes a third layer comprising an electrical energy accumulator constituting the autonomous electrical power supply unit;
the third layer comprises a substrate on which the electrical energy accumulator is printed;
the assembly includes a fourth layer forming a hidden face of the dial comprising the control unit;
the assembly includes a third layer comprising a hidden face of the dial including the control unit and an electrical energy accumulator constituting the autonomous electrical power supply unit;
the first layer is rigid relative to the other layers comprised in the assembly, which are supple.

Another aspect of the invention relates to a watch comprising such a dial.

Advantageously, the watch comprises a mechanical or electromechanical or electronic horological movement.

### BRIEF DESCRIPTION OF THE FIGURES

The purposes, advantages and features of the watch according to the invention will appear better in the following description on the basis of at least one non-limiting embodiment illustrated by the drawings wherein:

FIG. 1 shows a perspective view of a watch comprising a dial provided with an autonomous lighting device, according to one of the embodiments of the invention;

FIG. 2 shows an exploded view of a first variant of the assembly of four stacked layers forming said dial provided with the autonomous lighting device, said layers each including one or more constituent elements of the lighting device, according to a first embodiment of the invention;

FIG. 3 shows a schematic view of this first variant of the assembly of layers forming the dial provided with the autonomous lighting device according to the first embodiment of the invention;

FIG. 4 shows an exploded view of a second variant of the assembly of three stacked layers forming said dial provided with the autonomous lighting device, said layers each including one or more constituent elements of the lighting device according to a second embodiment of the invention, and

FIG. 5 shows a schematic view of this second variant of the assembly of layers forming the dial provided with the autonomous lighting device according to the second embodiment of the invention.

### DETAILED DESCRIPTION OF THE INVENTION

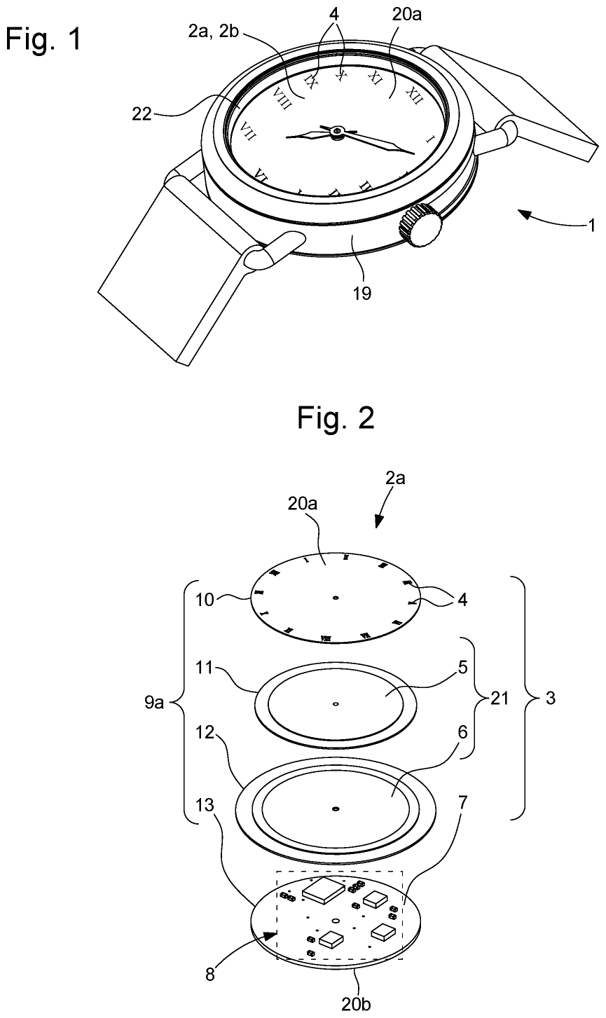

FIG. 1 shows a schematic representation of a watch 1 comprising a case 19 provided with a middle part to which a back and a crystal 22 are fixed, a set of components forming a horological movement, and a dial 2a, 2b disposed between the horological movement and the crystal 22.

In a manner known to the person skilled in the art, the horological movement drives a hand-fitting comprising an hour hand, a minute hand and possibly a second hand. To this end, the dial 2a, 2b includes a through hole receiving the axis of the hands. This dial 2a, 2b also comprises two faces 20a, 20b of which:
a face 20a visible from the outside of the watch 1, also called the “visible part” or “visible upper part” of this dial 2a, 2b, and
a face called hidden face 20b arranged opposite the horological movement in an enclosure of the case 19 of the watch 1, this face 20b being otherwise called the “hidden part” or “hidden lower part” of this dial 2a, 2b, 2b.

Such a visible face 20a comprises at least one graphic representation such as:
a reference (or display) element such as, for example, a number, an index, a line or else a dot contributing, with or without the hands, to the display of a horological information/measurement or a physical information/measurement measured by a sensor or the like comprised in the movement;
an inscription, pattern, text, logo, etc.

Moreover, it should be noted that in the embodiments illustrated in FIGS. 1 to 5, the dial 2a, 2b preferably has a circular shape. It is understood that the invention can also be implemented for dials 2a, 2b having other shapes such as, for example, a triangular shape or a shape similar to that of a quadrilateral.

In the embodiments of the invention, the horological movement is a mechanical movement. Alternatively, this movement may be an electronic movement or an electromechanical movement. Hereinafter, reference will be made to a mechanical watch when its movement is mechanical and to electromechanical and electronic watches when they include electromechanical and electronic movements respectively.

With reference to FIGS. 2 and 4, such a dial 2a, 2b comprises an autonomous lighting device 3. This lighting device 3 has its own electrical power supply, as will be seen later. Such a lighting device 3 is said to be autonomous in particular with respect to the movement of the watch 1 and in particular with respect to the energy source of this movement, for example when this source is an electrical power supply as in an electronic movement or an electromechanical movement. Under these conditions, it is understood that the energy used by this lighting device 3 is not to the detriment of the autonomy of the movement.

In this context, the dial 2a, 2b can be removably mounted in the watch 1 regardless of the type of watch 1. The only condition to be met is that the dial 2a, 2b comprises this lighting device 3, which is therefore independent of the movement of the watch 1.

This lighting device 3 comprised in this dial 2a, 2b, includes at least one luminous source 4 also called light source, an autonomous power supply unit 21 and a control unit 7.

In this context, the luminous source 4 may correspond to any electroluminescent element selected from a list comprising in a non-exhaustive and non-limiting manner:
an electroluminescent capacitor known by the acronym LEC (Light-Emitting Capacitor);
a light-emitting diode of the LED (acronym for “Light-Emitting Diode”), OLED (acronym for “Organic Light-Emitting Diode”), AMOLED (acronym for “Active-Matrix Organic Light-Emitting Diode”) or QLED (acronym for “Quantum Light-emitting diode”) type;
any electroluminescent material activated by a local electric field;
any electroluminescent material activated by an electric current;
any combination of these electroluminescent elements.

It should be noted that this luminous source 4 may, in certain embodiments of the invention, be a luminous source 4 capable of forming an extended luminous source. This allows to give a predetermined shape to the extended luminous source, typically, without this being exhaustive or limiting, a shape relating to a graphic representation of a number, letter, logo or text. It should also be noted that this luminous source 4 can produce light in any colour and/or in any direction.

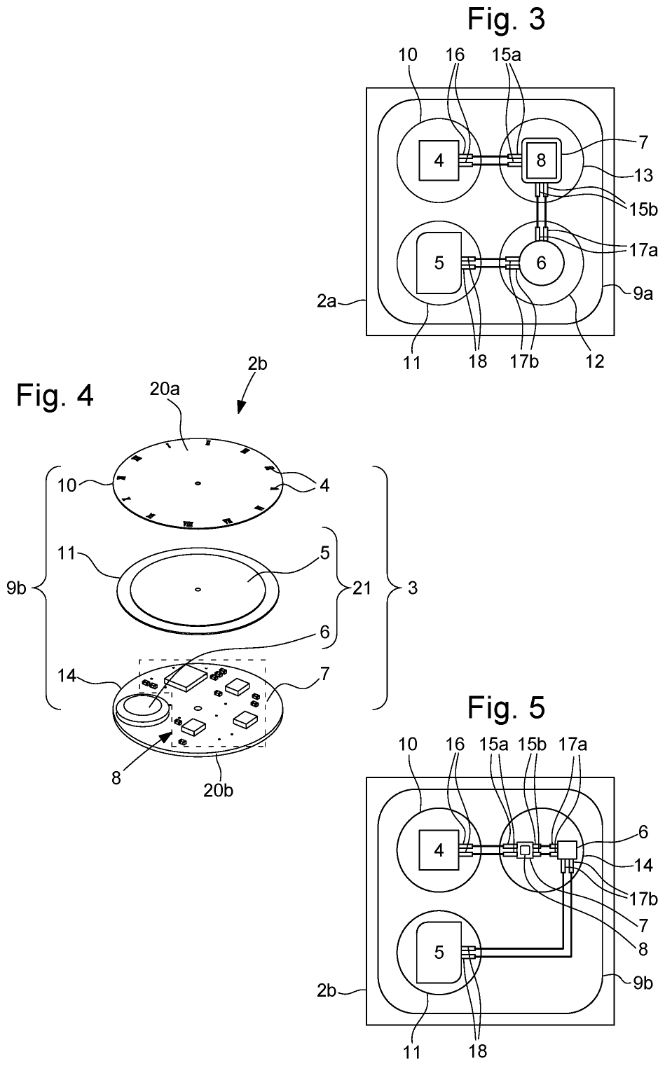

In this lighting device 3, the autonomous power supply unit 21 includes an electrical energy accumulator 6 and a photovoltaic module 5 comprising at least one photovoltaic cell, also known as a solar cell. This photovoltaic module 5 is connected to the electrical energy accumulator 6 via connection elements referenced 17b and 18 in FIGS. 3 and 5. This photovoltaic module 5 may comprise one or more elementary cells of the heterojunction or multijunction type, connected in parallel or in series. Each photovoltaic cell of this module 5 can be made, in a manner known to the person skilled in the art, from semiconductor materials based on copper, indium, gallium and selenium, based on cadmium telluride, based on monocrystalline gallium arsenide or based on monocrystalline or polycrystalline silicon, or with perovskites. It should be noted that these examples are not limitative and that the person skilled in the art will be able to find the type of photovoltaic cell suitable for the invention.

In this lighting device 3, the control unit 7, also known as a microcontroller, includes an electronic circuit 8 comprising hardware resources, in particular at least one processor cooperating with memory elements as well as address, data and control buses. This control unit 7 comprises in its memory elements an algorithm for managing the illumination of said at least one luminous source 4. Such an algorithm is executed by the processor of this control unit 7, taking account in particular of data from event sensors comprised in the lighting device 3 in order to manage the operation of said at least one luminous source 4.

It should be noted that such data may, for example, provide information relating to events detected by these sensors, said events being likely to contribute to the operation of said at least one luminous source 4. These events may comprise, in a non-limiting and a non-exhaustive manner: the detection of a particular level of luminosity in the environment of the watch 1, the detection of a particular sound element or a particular sound level, the detection of a particular visual object, the detection of a movement made by a part of the user's body on which this watch 1 is comprised, etc.

In this context, the event sensor of this autonomous lighting device 3 comprises in particular and in a non-limiting and non-exhaustive manner:
a brightness sensor allowing to detect the ambient light level;
a movement sensor for a part of the user's body comprising the watch 1, such as a gyroscopic and/or inertial sensor in the form of an electronic component of the gyroscopic and/or inertial electromechanical microsystem circuit type;
a microphone-type sound sensor, and/or
a photographic sensor-type optical sensor.

Moreover, when the lighting device 3 comprises several luminous sources 4, their operation can be managed/controlled by the control unit 7 simultaneously and/or in sequence. In addition, each luminous source 4 is managed/controlled by this control unit 7 separately. In this context, the management of the operation of each luminous source 4 may consist, in a non-limiting and non-exhaustive manner, of the following operations: sequential switching on or off, simultaneous switching on or off of two or more luminous sources 4, flashing of one or more luminous sources 4, definition of a flashing frequency for each luminous source 4, a flashing duration for each luminous source 4, a switching on or off duration for each luminous source 4, etc.

Such a control unit 7 may also comprise in its memory elements an algorithm for managing the electrical energy accumulator 6, in particular for managing its recharging by the photovoltaic module 5 and for managing the electrical consumption by said luminous source 4.

Thus, as mentioned above, the autonomous lighting device 3 is therefore comprised in the dial 2a, 2b. In this configuration, the components of this lighting device 3, namely the luminous source 4, the electrical energy accumulator 6, the photovoltaic module 5 and the control unit 7, are comprised in one or more layers 10, 11, 12, 13, 14 forming this dial 2a, 2b.

With reference to FIGS. 2 to 5, this dial 2a, 2b is formed by an assembly 9a , 9b of a plurality of layers 10, 11, 12, 13, 14 of material connected together. In this assembly 9a , 9b, these layers 10, 11, 12, 13, 14 are connected together by a connecting element such as an adhesive substance so as to unify them in order to obtain a monolithic assembly 9a , 9b thus forming a one-piece dial 2a, 2b. This connecting element may also be a clip or else a screw. Such layers 10, 11, 12, 13, 14 are stacked in the assembly 9a , 9b, that is to say they are arranged one above the other in this dial 2a, 2b in a defined order.

Thus, such a one-piece dial 2a, 2b further has the advantage of being removably mounted in the case 19 of the watch 1, in addition to facilitating its integration into this case 19.

In a first variant of this assembly 9a illustrated in FIG. 3, it is made up of four successive layers 10, 11, 12, 13 as follows:
a first layer 10 forming/constituting the visible face 20a of the dial 2a including said at least one luminous source 4 of the lighting device 3,
a second layer 11 including the photovoltaic module 5;
a third layer 12 including an electrical energy accumulator 6, also known as a rechargeable battery, and
a fourth layer 13 forming the hidden face 20b of the dial 2a including the control unit 7.

The first layer 10 of this assembly 9a is preferably rigid or semi-rigid in comparison with the second, third and fourth layers 11, 12, 13 which are preferably supple or flexible. It is understood here that such a first layer 10 helps to structurally stiffen the assembly 9a and therefore the dial 2a.

In this assembly 9a , the first, second, third and fourth layers 10, 11, 12 and 13 each comprise an upper surface and a lower surface.

The first layer 10 is formed by a transparent or translucent or at least partially transparent or at least partially translucent rigid or semi-rigid substrate. Such a substrate is made of a material with a transmittance to solar radiation, in particular ultraviolet radiation, also known as UVT (for “Ultra-Violet Transmission”) comprised between 65 and 95 percent. This transmittance is preferably 85 percent. Such a material can be transparent or translucent. This material can, in a non-exhaustive and non-limiting manner, be a polymer, glass or ceramic.

In this context, it is understood that this substrate is configured so that:
the light produced by said at least one luminous source can escape to the outside of the dial 2a, 2b and therefore of the watch 1, and
the light from the surroundings of the watch 1 can penetrate the dial 2a, 2b towards the photovoltaic module 5 of the lighting device 3, this light comprising solar radiation when it is of natural origin.

In other words, this transparent or translucent substrate is configured to be traversed by solar radiation likely to power supply the photovoltaic module 5 so that the latter can convert the solar energy from this radiation into electrical energy.

This first layer 10 also comprises at least one luminous source 4 which is arranged in the body of the substrate. Such an arrangement of the luminous source 4 in this substrate is configured to provide lighting of all or part of the visible face 20a of the dial 2a. For example, lighting of a graphic representation such as a reference (or display) element like a number, an index, a line, a dot or lighting of one or more hands, or lighting of all or part of the surface of the visible face of the dial 2a. In one variant, this luminous source 4 can have a predetermined shape such as the shape of a number, a letter, an index, a line, a dot, a logo or else a text.

This lighting can be backlighting or semi-direct lighting when the luminous source 4 is arranged in a cavity defined in the substrate. More precisely, this cavity can be a blind opening made in the lower surface of the substrate. In this configuration, when the back of this cavity comprises a graphic representation, the light radiation, or the light, produced by this luminous source 4 can escape to the outside of the dial 2a via the visible face 20a of this dial 2a, thus allowing at least one graphic representation to be viewed in the dark. In particular, the light radiation escaping from the visible face 20a draws the outline of this graphic representation. In this context, this graphic representation comprised in or on the upper surface or else on the lower surface of the substrate forming the first layer 10, is preferably opaque or non-translucent or non-transparent.

This lighting can be direct lighting when the luminous source 4 is arranged in a cavity defined in the substrate. This cavity can be a blind opening made in the lower surface of this substrate, the back of which is devoid of any graphic representation. In this configuration, the light radiation, or the light, produced by this luminous source 4 can escape through the back of this cavity towards the outside of the dial 2a and therefore through the visible face 20a of this dial 2a.

This lighting can also be direct lighting when the luminous source 4 is arranged in a through opening extending through the thickness of the substrate of the first layer 10, opening at its two ends respectively into the upper and lower surfaces of this substrate. In this configuration, all or part of the luminous source 4 can protrude from the upper surface of this substrate and therefore from the first layer 10 or from the visible face 20a of the dial 2a to form a graphic representation such as an index, a number, a dot, a line, etc.

Such lighting can also be remote lighting when the at least one luminous source 4 is coupled to at least one waveguide. This waveguide, also known as a light guide, allows to bring the light from the point where it is injected into the guide to the substrate or to an area of the substrate (e.g. cavity, through opening) close to the upper surface of this substrate. Such a light guide may be an optical fibre that allows any obstacles that may arise in the substrate to be bypassed, for example between the electroluminescent element and the area of the substrate close to the upper surface of the substrate, through which the light will escape. In this variant, it is therefore the light that is brought, via the waveguide, from the electroluminescent element to this area of the substrate to be illuminated.

In such a configuration, a first end of the waveguide is coupled to the luminous source 4 and a second end of the waveguide can be arranged in:
a cavity which may be a blind opening made in the lower surface of the substrate of this first layer 10, or
a through opening extending through the thickness of the substrate of the first layer 10 and opening at its two ends respectively into the upper and lower surfaces of this substrate and therefore of the first layer 10. This second end can thus protrude from the upper surface of the substrate or of this first layer 10 or from the visible face 20a of the dial 2a in order, for example, to form a graphic representation of this dial 2a such as, for example, a reference element such as an index, a number, a dot, a line, etc.

In this context, indirect lighting can be achieved by a single luminous source 4 comprised on the lower surface of the substrate of this first layer 10 and coupled to several waveguides, the second ends of which are arranged in:
cavities each emitting light radiation from this luminous source 4, this radiation escaping to the outside of the dial 2a via the visible face 20a, thus enabling at least one graphic representation to be viewed in the dark. In this context, this graphic representation comprised in or on the visible face 20a of the dial 2a, or the upper surface of the substrate, is preferably opaque, and/or
through openings protruding or not from the upper surface of this substrate in order to form reference elements such as an index, line or else a dot, and each emitting light radiation from this luminous source 4.

In this first layer 10, the luminous source 4 is applied/fixed to the lower surface of the substrate of this first layer 10, in a cavity or on an internal wall of a through opening mentioned previously, by printing or evaporation.

Furthermore, it should be noted that the lower surface of this first layer 10 can be self-adhesive so that it can be assembled to the second layer 11.

In this assembly 9a , the second layer 11 comprises a substrate including the photovoltaic module 5. Such a substrate is preferably flexible or supple. The substrate of the second layer 11 may be a film on which the photovoltaic module 5 is disposed, or it may be made of a material belonging to the polymer family.

In this second layer 11, the photovoltaic module 5 extends preferentially over the whole of an area called active area of the upper surface of this substrate. This active area is a portion of the upper surface of the substrate which is able to receive light from the lower surface of the first layer 10 of the dial 2a. This light, which has passed through all or part of the first layer 10, comes from the external environment of the dial 2a, and therefore of the watch 1, in this case mainly from solar radiation when it is of natural origin.

It should be noted that the photovoltaic module 5 is applied to the upper surface of this substrate using inkjet or screen printing methods or using thermal evaporation printing methods. Reference will be made here to a second layer 11 comprising a printed photovoltaic module 5. In particular, a photovoltaic module 5 printed on the substrate of the second layer 11.

It will be noted that once the photovoltaic module 5 was applied to the substrate, a layer of a self-adhesive substance can be deposited on all or part of the upper surface and/or the lower surface of the substrate. Under these conditions, the second layer 11 may be a self-adhesive layer which helps to facilitate its assembly with the other layers, in particular with the first layer 10 and/or the third layer 12 of this assembly 9a.

In the assembly 9a , this third layer 12 also comprises a preferably flexible or supple substrate, including the electrical energy accumulator 6 of the autonomous lighting device 3. This substrate of the third layer 12 may be a film on which the accumulator 6 is comprised. Such a substrate may be made of a material belonging to the polymer family.

This accumulator 6 may be a lithium battery or a semiconductor battery. Such an accumulator 6 is applied to the upper surface of this substrate using methods known in the prior art, such as:
Methods for printing on a flexible polymer substrate, for example a lithium battery, or
three-dimensional printing methods, for example for a semi-conductor battery such as a semi-conductor lithium-metal battery.

Here reference will be made to a third layer 12 comprising a printed electrical energy accumulator 6. In particular, an electrical energy accumulator 6 printed on the substrate of the third layer 12.

Thus, such methods allow to obtain a third layer 12 comprising this accumulator 6 which is supple and ultra-fine.

Furthermore, it will be noted that once the accumulator 6 has been applied to the substrate, a layer of a self-adhesive substance can be deposited on all or part of the upper surface and/or the lower surface of this substrate. Under these conditions, the third layer 12 may be a self-adhesive layer which helps to facilitate its assembly with the other layers, in particular with the second layer 11 and/or the fourth layer 13 of this assembly 9a.

Note that this accumulator 6 is used to store the electrical energy produced by the photovoltaic module 5 and to release it on demand to power supply said at least one luminous source 4.

In this assembly 9a , this fourth and final layer 13 forms the hidden face of the dial 2a. Such a fourth layer 13 is formed by a preferably flexible or supple substrate, including the control unit 7. Such a substrate of the fourth layer 13 may, for example, be a flexible PCB on which this control unit 7 is arranged, in particular on the upper surface of this PCB and therefore of the substrate. In this context, the construction of the control unit 7 on this upper surface of the substrate can be carried out using three-dimensional printing methods or polymer printing methods.

In the second variant, the assembly 9b forming the dial 2b comprises three interconnected layers 10, 11, 14. Therefore, note that this second variant differs from the first variant in that it comprises three layers 10, 11, 14 instead of four layers 10, 11, 12, 13, as in the first variant. In this second variant, the electrical energy accumulator 6 of the autonomous lighting device 3 is now comprised in the third and last layer 14 of this assembly 9b with the control unit 7.

Such a third and final layer 14 of this assembly 9b, forming the hidden face of the dial 2b, consists of a preferably flexible or supple substrate, on which are constructed, preferably on the upper surface of this substrate, the accumulator 6 and the electronic circuit 8 constituting the control unit 7.

Such construction of the accumulator 6 and the control unit 7 on this upper surface of the substrate can be carried out using three-dimensional printing methods or polymer printing methods. It should be noted that such a substrate can be, for example, a flexible PCB.

In summary, in this second variant, the assembly 9b then comprises:
a first layer 10 forming the visible face 20a of the dial 2b including said at least one luminous source 4 of the lighting device 3;
a second layer 11 including the photovoltaic module 5, and
the third layer 14 forming the hidden face 20b of the dial 2b including the accumulator 6 and the control unit 7.

Note that in this second variant, the first and second layers 10, 11 are similar to those of the first variant of the assembly 9a.

Moreover, with reference to FIGS. 3 and 5, the electronic circuit 8 of the control unit 7 comprises first connection elements 15a which are connected to connection elements 16 of said at least one luminous source 4 for managing the operation of this luminous source 4. This electronic circuit 8 also comprises second connection elements 15b connected to first connection elements 17a of the accumulator 6.

Furthermore, it should be noted that the above-mentioned event sensors of the lighting device 3 are preferably arranged in the first layer 10 and/or the last layer 13, 14 of the assembly 9a , 9b and are connected to the control unit 7 of this device 3.

In a third variant not shown, the dial assembly comprises two interconnected layers. Note that this third variant differs from the second variant in that it comprises two layers instead of three layers 10, 11, 14, as in this second variant. In this third variant, the photovoltaic module 5 of the autonomous lighting device 3 is now comprised in the first layer and in particular on the lower surface of the substrate forming this first layer. This photovoltaic module 5 can be applied to this lower surface of the substrate of this first layer using inkjet or screen printing methods or using thermal evaporation printing methods. It should therefore be noted that this first layer is then similar to the first layers 11 of the first and second variants, except that in this third variant, the first layer additionally comprises the photovoltaic module.

Moreover, in the third variant, and similarly to the second variant, the electrical energy accumulator 6 of the autonomous lighting device 3 is comprised in the second and final layer of this assembly with the control unit 7. Such a second layer, forming the hidden face of the dial, consists of a preferably flexible or supple substrate, on which are constructed, preferably on the upper surface of this substrate, the accumulator 6 and the electronic circuit 8 constituting the control unit 7. This construction of the accumulator 6 and the control unit 7 on the upper surface of the substrate can be carried out using three-dimensional printing methods or polymer printing methods. It should be noted that such a substrate can be a flexible PCB, for example.

In summary, in this third variant, the assembly then comprises:
a first layer forming the visible face 20a of the dial including said at least one luminous source 4 and the photovoltaic module 5 of the lighting device 3, and
a second layer forming the hidden face 20b of the dial including the accumulator 6 and the control unit 7.

It goes without saying that the present invention is not limited to the embodiments that have been just described and that various simple modifications and variants may be considered by the person skilled in the art without departing from the scope of the invention as defined by the appended claims.

1. A dial for a watch comprising an autonomous lighting device comprising the following functional elements:
at least one luminous source,
an autonomous power supply unit, and
a control unit for managing the operation of said at least one luminous source,
said dial being formed by an assembly of a plurality of stacked layers connected together and each including one or more functional elements of the autonomous lighting device.

2. The dial according to claim 1, wherein the assembly includes a first layer forming a visible face of the dial comprising at least one luminous source.

3. The dial according to claim 1, wherein said first layer is configured to be traversed in whole or in part by light radiation, in particular solar radiation.

4. The dial according to claim 1, wherein said first layer is wholly or partly transparent or translucent.

5. The dial according to claim 1, wherein the assembly includes a second layer comprising a photovoltaic module constituting the autonomous electrical power supply unit.

6. The dial according to claim 1, wherein the second layer comprises a substrate on which a photovoltaic module is printed.

7. The dial according to claim 1, wherein said the second layer comprises a substrate on which a photovoltaic module is disposed on an active area of said second layer, said area being configured to receive light rays from the first layer of the assembly.

8. The dial according to claim 1, wherein the assembly includes a third layer comprising an electrical energy accumulator constituting the autonomous electrical power supply unit.

9. The dial according to claim 1, wherein the assembly includes a third layer comprising a substrate on which the electrical energy accumulator is printed.

10. The dial according to claim 1, wherein the assembly includes a fourth layer forming a hidden face of the dial comprising the control unit.

11. The dial according to claim 1, wherein the assembly includes a third layer comprising a hidden face of the dial including the control unit and an electrical energy accumulator constituting the autonomous electrical power supply unit.

12. The dial according to claim 1, wherein the first layer is rigid relative to the other layers comprised in the assembly which are supple.

13. A watch comprising a dial according to claim 1.

14. The watch according to claim 13, wherein the watch comprises a mechanical or electromechanical or electronic horological movement.
